(19) United States
(12) Patent Application Publication
(10) Pub. No.: US 2025/0211233 A1
(43) Pub. Date: Jun. 26, 2025

(54) SYSTEM AND METHOD FOR INCREASING TRANSCONDUCTANCE OF A CMOS INVERTER

(71) Applicant: Stichting IMEC Nederland, Eindhoven (NL)

(72) Inventors: Anoop Bhat, Veldhoven (NL); Zule Xu, Helmond (NL)

(21) Appl. No.: 18/976,600

(22) Filed: Dec. 11, 2024

(30) Foreign Application Priority Data
Dec. 21, 2023 (EP) 23219084.3

(51) Int. Cl. H03K 19/0948

(52) U.S. Cl. CPC H03K 19/0948

(57) ABSTRACT

A system is provided for increasing the transconductance of a CMOS inverter. The system comprises a biasing circuit configured to provide a supply voltage to the CMOS inverter, wherein the biasing circuit comprises at least one transistor arrangement, wherein the transistor arrangement and the CMOS inverter are interconnected via back gates of respective transistors. The system further comprises a control circuit configured to provide a bias voltage to the interconnected back gates when the supply voltage reaches a threshold value, whereby both the biasing circuit and the control circuit together control the transconductance of the CMOS inverter.

### CROSS-REFERENCE TO RELATED APPLICATIONS

The present application is a non-provisional patent application claiming priority to European Patent Application No. 23219084.3, filed Dec. 21, 2023, the contents of which are hereby incorporated by reference.

### FIELD OF THE DISCLOSURE

The disclosure relates to the enhancement of the performance of inverter-based circuits, such as to the enhancement of the transconductance range of the Complementary Metal-Oxide Semiconductor (CMOS) inverter of the inverter-based circuits.

### BACKGROUND

Radio frequency (RF) receivers may include many inverter-based circuits, such as Low-Noise Transconductance Amplifiers (LNTAs), Transimpedance Amplifiers (TIAs), Low-Pass Filters (LPFs), to reduce the overall power and to increase the linearity. For example, the transconductance of the inverters of the inverter-based circuits may be controlled across the temperature and supply voltage variations in order to provide an improved performance.

For example, the document Jansen et al., Complementary constant-gm biasing of Nauta-transconductors in low-power Gm-C filters to +/−2% accuracy over temperature, Pages 466-469, 2012 Proceedings of the ESSCIRC, 2013, doi: 10.1109/JSSC.2013.2253233 discloses a static complementary constant-transconductance biasing circuit for CMOS inverter-based filters; however, the transconductance range of the CMOS inverter is limited by the supply voltage of the CMOS inverter.

Accordingly, the disclosure herein is to provide a system and a method for increasing the transconductance range of a CMOS inverter.

### SUMMARY

The object of the disclosure herein is solved by the features of the first independent claim for the system and by the features of the second independent claim for the method. The dependent claims contain further developments.

According to an example implementation of the disclosure, a system is provided for increasing the transconductance of a CMOS inverter. The system comprises a biasing circuit configured to provide a supply voltage to the CMOS inverter, wherein the biasing circuit comprises at least one transistor arrangement, wherein the transistor arrangement and the CMOS inverter are interconnected via back gates of respective transistors.

In addition, the system comprises a control circuit configured to provide a bias voltage to the interconnected back gates when the supply voltage reaches a threshold value, whereby both the biasing circuit and the control circuit (e.g., together) control the transconductance of the CMOS inverter.

In an example embodiment, the transconductance range of the CMOS inverter can be extended beyond the range provided by the supply voltage (e.g., by the application) of the bias voltage at the interconnected back gates of the respective transistors. Furthermore, the control circuit may facilitate an automatic control of the transconductance of the CMOS inverter over the extended transconductance range of the CMOS inverter.

In one embodiment, the control circuit is further configured to maintain the supply voltage to the CMOS inverter when the supply voltage is higher than the threshold value. This may (e.g., automatically) increase the transconductance range while having control on the transconductance of the CMOS inverter.

In one embodiment, the transistor arrangement comprises at least one replicated CMOS inverter corresponding to a scaled version of the CMOS inverter and at least one resistor, such as a tunable resistor, operably connected to the replicated CMOS inverter.

In this regard, the transistor arrangement is configured to control the transconductance of the CMOS inverter with (e.g., by means of) the replicated CMOS inverter and the resistor. In an example embodiment, the transconductance of the CMOS inverter can be (e.g., effectively) controlled via a resistor value, such as via the tunable resistor, across voltage and temperature in order to compensate for the voltage and temperature variations. For example, the resistor value may be a predetermined (e.g., known) resistor value, which may facilitate an (e.g., effective) tuning of the resistor.

In one embodiment, the biasing circuit is configured to provide the supply voltage ranging from a predefined minimum value to the threshold value. In this regard, the predefined minimum value is provided based on a minimum linearity criteria of the transconductance of the CMOS inverter.

Additionally or alternatively, the threshold value is provided based on an operation criteria of the transistor arrangement. The operation criteria to provide the threshold value may correspond to the maximum supply voltage that can be provided to the CMOS inverter by the biasing circuit. In an example embodiment, a maximum linearity of the transconductance of the CMOS inverter, such as at the lower range of the transconductance, can be provided.

In one embodiment, the transistor arrangement of the biasing circuit is configured to control the transconductance of the CMOS inverter for the supply voltage ranging from the predefined minimum value to the threshold value. In this regard, the transconductance is inversely proportional to the resistor of the transistor arrangement. In an example embodiment, a maximum possible linearity of the transconductance of the CMOS inverter over the transconductance range can be provided.

In one embodiment, the control circuit is configured to provide the bias voltage to the interconnected back gates ranging from zero to a supply voltage of the biasing circuit. In an example embodiment, a maximum possible supply voltage can be maintained for a given transconductance value of the CMOS inverter.

In one embodiment, the transistor arrangement of the biasing circuit is configured to control the transconductance of the CMOS inverter for the bias voltage to the interconnected back gates ranging from zero to the supply voltage of the biasing circuit. In an example embodiment, a maximum possible linearity of the transconductance of the CMOS inverter over the extended transconductance range can be provided.

In one embodiment, the control circuit comprises at least one comparator, such as an operational amplifier comparator, configured to sense the supply voltage from the biasing circuit and further to compare the supply voltage with the threshold value.

In this regard, the comparator is configured to (e.g., exclusively) feed the supply voltage to the transistor arrangement and the CMOS inverter when the supply voltage is lower than the threshold value and to additionally feed the bias voltage to the interconnected back gates of the respective transistors of the transistor arrangement and the CMOS inverter when the supply voltage reaches the threshold value.

In an example embodiment, the transconductance range of the CMOS inverter can be increased, which may allow to ensure maximum transconductance even with variations in the voltage and temperature. The range of the transconductance value that can be controlled over the temperature range and the supply voltage range for every transconductance value can be maximized.

In one embodiment, the respective transistors of the transistor arrangement and the CMOS inverter are Fully-Depleted Silicon-on-Insulator (FDSOI) transistors.

According to an example implementation of the disclosure, a method is provided for increasing the transconductance of a CMOS inverter. The method comprises the step of providing, by a biasing circuit, a supply voltage to the CMOS inverter, wherein at least one transistor arrangement of the biasing circuit and the CMOS inverter are interconnected via back gates of respective transistors.

Furthermore, the method comprises the step of providing, by a control circuit, a bias voltage to the interconnected back gates when the supply voltage reaches a threshold value. Moreover, the method comprises the step of controlling, together with the biasing circuit and the control circuit, the transconductance of the CMOS inverter.

In one embodiment, the method further comprises the step of maintaining, by the control circuit, the supply voltage to the CMOS inverter when the supply voltage is higher than the threshold value.

In one embodiment, the method further comprises the steps of providing, by the biasing circuit, the supply voltage ranging from a predefined minimum value to the threshold value, and providing, by the control circuit, the bias voltage to the interconnected back gates ranging from zero to a supply voltage of the biasing circuit.

In one embodiment, the method further comprises the steps of controlling, by the transistor arrangement, the transconductance of the CMOS inverter for the supply voltage ranging from the predefined minimum value to the threshold value, and controlling, by the transistor arrangement, the transconductance of the CMOS inverter for the bias voltage to the interconnected back gates ranging from zero to the supply voltage of the biasing circuit.

The method may correspond to the system and its implementation forms. Accordingly, the method may have corresponding implementation forms. Further, the method may provide the same usefulness as the system and its respective implementation forms.

### BRIEF DESCRIPTION OF THE FIGURES

The above, as well as additional, features will be better understood through the following illustrative and non-limiting detailed description of example embodiments, with reference to the appended drawings.

Exemplary embodiments of the disclosure are now further explained with respect to the drawings by way of example only, and not for limitation. In the drawings:

FIG. 1 shows a first exemplary embodiment of the system according to an embodiment of the disclosure;

FIG. 2 shows an exemplary process flow of the system according to an embodiment of the disclosure;

FIG. 3A shows an exemplary relationship between the transconductance and the supply of CMOS inverters;

FIG. 3B shows an exemplary relationship between the transconductance and the supply, and the transconductance and the back gate voltage of the CMOS inverter according to an embodiment of the disclosure;

FIG. 4 shows a second exemplary embodiment of the system according to an embodiment of the disclosure;

FIG. 5 shows an exemplary tuning effect of the resistor on the parameters of the CMOS inverter according to an embodiment of the disclosure; and

FIG. 6 shows an exemplary embodiment of the method according to an embodiment of the disclosure.

The figures are schematic, not necessarily to scale, and generally show parts which elucidate example embodiments, wherein other parts may be omitted or suggested.

### DETAILED DESCRIPTION

Reference will now be made in detail to the embodiments of the present disclosure, examples of which are illustrated in the accompanying drawings. The following embodiments of the present disclosure may be variously modified and the range of the present disclosure is not limited by the following embodiments. The embodiments herein are provided by way of example. Furthermore, like numbers refer to the same or similar elements or components throughout.

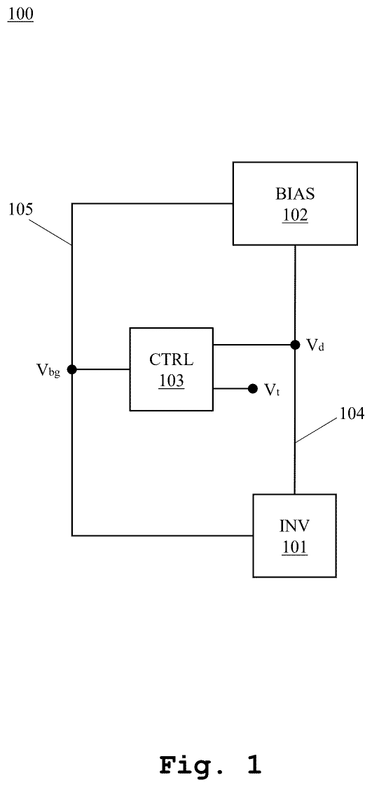

In FIG. 1, a first exemplary embodiment of the system 100 according to the first embodiment of the disclosure is illustrated. The system 100 may control one or more parameters of an inverter 101. The system 100 may comprise the inverter 101 or may act as a stand-alone system operably connected to the inverter 101.

For example, the inverter 101 may correspond to any inverter-based blocks, such as LNTA, TIAs, LPF, of an RF receiver. For example, the inverter 101 may comprise one or more FDSOI transistors, such as one FDSOI PMOS transistor and one FDSOI NMOS transistor arranged in a complementary manner.

For example, the system 100 may comprise a biasing circuit 102 connected to the inverter 101 via a supply line 104. The biasing circuit 102 may correspond to a (e.g., suitable) complementary constant-transconductance (Gm) biasing circuit. The biasing circuit 102 may provide a supply voltage Vd to the inverter 101, e.g., via the supply line 104. The biasing circuit 102 may comprise at least one transistor arrangement, such as comprising FDSOI transistors.

In this regard, the FDSOI transistors of the biasing circuit 102 and the FDSOI transistors of the inverter 101 may be interconnected via back gates of respective transistors, e.g., respective FDSOI PMOS transistors and respective FDSOI NMOS transistors, via a bias line 105.

For example, the system 100 may comprise a control circuit 103 connected to the supply line 104 and further to the bias line 105. The control circuit 103 may (e.g., continuously) sense or monitor the supply voltage Vd at the supply line, and may compare the supply voltage Vd with a threshold voltage Vt.

It is to be noted that the threshold voltage Vt may be internally generated by the control circuit 103. Alternatively, the threshold voltage Vt may be externally fed to the control circuit 103, e.g., from an external signal generation unit connected to the control circuit 103.

The following implementation regarding back gate biasing (e.g., via a back gate bias voltage Vbg) is illustrated for the NMOS transistor of the CMOS inverter 101 for simplicity.

For example, the control circuit 103 may provide the bias voltage Vbg to the interconnected back gates, e.g., via the bias line 105, when the supply voltage Vd becomes equal to the threshold voltage Vt. However, if the supply voltage Vd is less than the threshold voltage Vt, the control circuit 103 may maintain the supply voltage Vd and may set the bias voltage Vbg to zero.

Accordingly, the control circuit 103 may additionally feed the bias voltage Vbg to the interconnected back gates of the respective FDSOI transistors of the biasing circuit 102 and the inverter 101 when the supply voltage Vd becomes equal to the threshold voltage Vt, while maintaining the supply voltage Vd to the FDSOI transistors of the biasing circuit 102 and of the inverter 101.

As such, the bias circuit 102 and the control circuit 103 may (e.g., collectively) control the Gm range of the inverter 101, such as to increase the Gm range beyond the range provided (e.g., limited) by the supply voltage Vd, with (e.g., by means of) the additional bias voltage Vbg at the interconnected back gates of the respective FDSOI transistors.

Furthermore, with (e.g., by means of) the (e.g., constant) sensing and comparison of the supply voltage Vd with the threshold voltage Vt, the control circuit 103 may provide an (e.g., automatic) control of the Gm of the inverter 101 over the extended Gm range of the inverter 101.

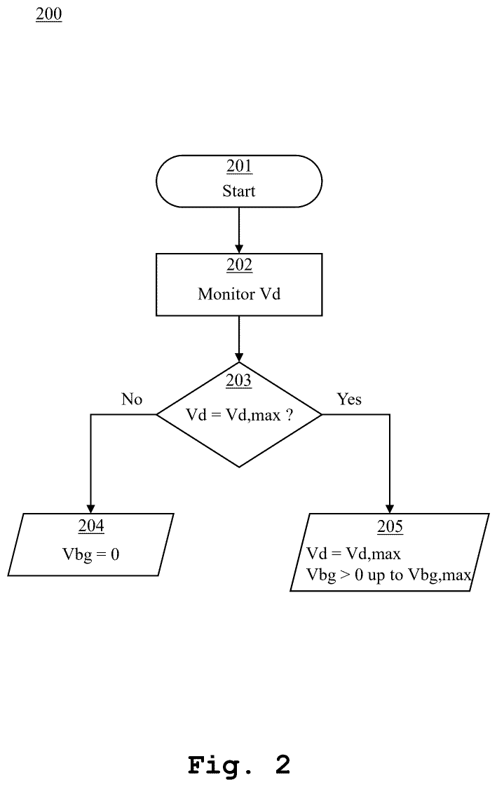

In FIG. 2, an exemplary algorithm 200 of the system 100 is illustrated via a process flow diagram. For example, the implementation regarding the bias voltage Vbg is illustrated for the NMOS transistor of the CMOS inverter 101.

For example, during the initiation phase 201, the biasing circuit 102 may supply the supply voltage Vd to the inverter 101 and further to the inverter arrangement of the biasing circuit 102, such as to ensure the (e.g., proper) operation of the inverter 101. Moreover, the control circuit 103 may be connected to the supply line 104 and further to the bias line 105 that may interconnect the back gates of the respective transistors of the biasing circuit 102 and the inverter 101.

During the monitoring phase 202, which may run during (e.g., along) the initiation phase 201, the control circuit 103 may (e.g., continuously) monitor the supply voltage Vd with respect to the threshold voltage Vt.

During the decision phase 203, the control circuit 103 may sense whether the supply voltage Vd is less than the threshold voltage Vt or is equal to the threshold voltage Vt.

If the supply voltage Vd is less than the threshold voltage Vt, the control circuit 103 may (e.g., only) maintain the supply voltage Vd by setting the bias voltage Vbg to zero, thereby resulting a phase 204 of the process flow.

However, if the supply voltage Vd becomes equal to the threshold voltage Vt, the control circuit may maintain the supply voltage Vd and may additionally supply the bias voltage Vbg to the interconnected back gates of the respective transistors, thereby resulting an alternative phase 205 of the process flow.

Therefore, the process flow diagram is a (e.g., use case) example in order to maintain a constant transconductance over temperature and supply voltage variations, such that (a) from the flow of phase 203 to the flow of phase 204, e.g., if the supply voltage Vd is less than the threshold voltage Vt, a constant Gm of the CMOS inverter 101 may be maintained by solely controlling the supply voltage Vd to the CMOS inverter 101 by setting the bias voltage Vbg=0, and (b) from the flow of phase 203 to the flow of phase 205, e.g., if the supply voltage Vd is equal or greater than the threshold voltage Vt, the bias voltage Vbg may be supplied to the interconnected back gates and may be controlled accordingly to maintain a constant Gm of the CMOS inverter 101.

Additionally, the process flow from phase 203 to phase 205 may be used for a further example that may use an inverter with a Gm, which is higher than the Gm range (e.g., solely) provided by the supply voltage Vd of the inverter.

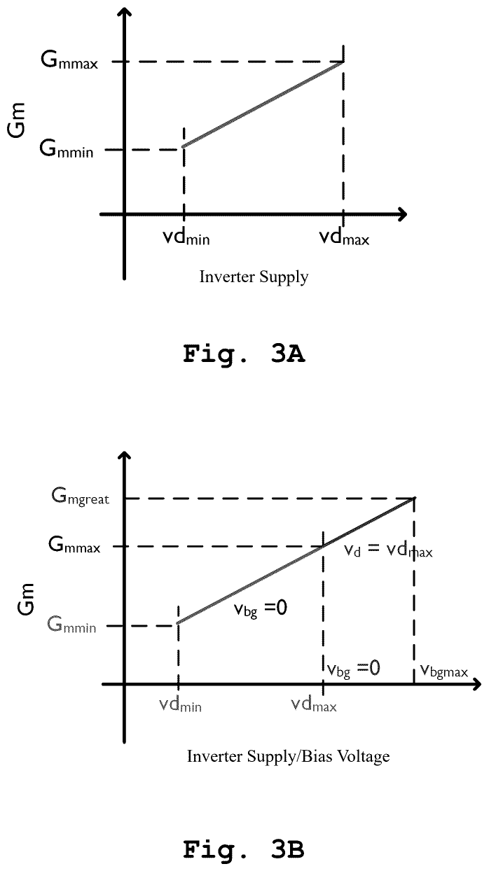

In FIG. 3A, an exemplary relationship between the Gm and the supply of CMOS inverters is illustrated, where the Gm may be controlled by a suitable (e.g., conventional) complementary constant-Gm biasing circuit.

In one example embodiment, the complementary constant-Gm biasing circuit may control the inverter supply voltage such that the Gm of the inverter is inversely proportional to a control resistor of the complementary constant-Gm biasing circuit. Since the resistor value may be known (or determined) across supply voltage and temperature, the Gm of the inverter can be controlled over the GM range and further maintained constant at a (e.g., desired) GM value by adjusting the resistance value of the control resistor which in turns adjusts the inverter supply accordingly.

Generally, the Gm of the inverter can be expressed as the ratio of the output current to the input voltage of the inverter. In order to provide reliable performance, the Gm may be regulated over supply voltage and temperature variation. The control resistor of the complementary constant-Gm biasing circuit may vary the inverter supply in order to determine the Gm of the inverter, where the input and output nodes of the inverter may be unaffected in order not to disturb the signal flow.

Since the control resistor may control the supply voltage of the inverter in order to control the Gm of the inverter, where the Gm may be limited by the inverter supply voltage as well.

Turning back to FIG. 3A, the horizontal axis denotes the inverter supply voltage and the vertical axis denotes the Gm. As shown, the lower side of the Gm, e.g., the Gmmin, is limited by the minimum inverter supply Vdmin in order to meet (e.g., satisfy) the minimum linearity criteria of for the inverter, whereby the upper side of the Gm, e.g., the Gmmax, is limited by the maximum inverter supply Vdmax. In some suitable setups, the complementary constant-Gm biasing circuit may not operate after reaching Vdmax; however, this disclosure provides operation beyond the Vdmax.

In FIG. 3B, an exemplary relationship between the Gm and the supply of the inverter 101 is illustrated according to the first embodiment of the disclosure. In order to overcome the limitation of Vdmax on the upper side of the Gm, the back gates of the respective transistors of the biasing circuit 102 and the inverter 101 may be interconnected and may be fed with the bias voltage Vbg by the control circuit 103, thereby extending the inverter supply voltage range.

In FIG. 3B, the horizontal axis denotes the inverter supply voltage Vd and the bias voltage Vbg. The vertical axis denotes the Gm of the inverter 101. It can be seen that, similar to FIG. 3A, the lower side of the Gm, e.g., the Gmmin, may be limited by the minimum inverter supply Vdmin in order to satisfy the minimum linearity criteria of for the inverter 101, however, the upper side of the Gm in relation to FIG. 3A, e.g., the Gmmax, is now extended further to Gmgreat, due to the application of the bias voltage Vbg to the interconnected back gates while maintaining the supply voltage Vd.

In this regard, as previously described in relation to FIG. 1 and FIG. 2, the biasing circuit 102 may provide the supply voltage Vd to the inverter 101 and the control circuit 103 may (e.g., continuously) sense the supply voltage Vd with respect to the threshold voltage Vt, which is shown here as the maximum inverter supply Vdmax.

In this regard, the control circuit 103 may (e.g., exclusively) maintain the supply voltage Vd to the inverter 101 over the range Vdmin to Vdmax, such as by setting the bias voltage Vbg at the interconnected back gates to zero. When the supply voltage Vd reaches its highest limit Vdmax, the control circuit 103 may apply the bias voltage Vbg to the interconnected back gates while maintaining the supply voltage Vd at its maximum limit Vdmax.

Accordingly, the Gm of the inverter 101 can be (e.g., effectively) increased from the maximum limit Gmmax of FIG. 3A to a greater limit Gmgreat while (e.g., simultaneously) extending the inverter supply from the maximum limit Vdmax of FIG. 3A to a greater limit Vdmax, which may correspond to the supply voltage of the biasing circuit 102.

For simplicity, the increase in the bias voltage Vbg is illustrated for the NMOS transistor of the CMOS inverter 101. It is further noted that the linear relationship between the Gm and inverter supply, as shown in FIG. 3A and FIG. 3B, are shown (e.g., only) for illustration purposes, and the relationship, e.g., the curve, may be of a higher order polynomial.

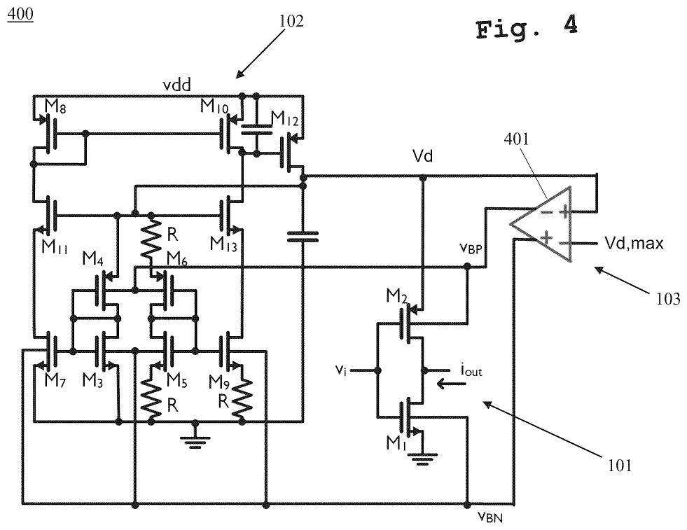

In FIG. 4, a second exemplary embodiment of the system 400 according to the first embodiment of the disclosure is illustrated. In one example embodiment, the system 400 shows the internal circuital arrangement of the system 100. For example, the inverter 101 may comprise the complementary FDSOI NMOS M1 and PMOS M2, where Vi may denote the input voltage and iout may denote the output voltage of the inverter 101. As such, the Gm of the inverter 101 can be expressed as:

$$\begin{matrix}{G}_{m} = \frac{{i}_{out}}{{V}_{i}} \\ {G}_{m} = {G}_{m , n} + {G}_{m , p}\end{matrix}$$

G_{m,n} and G_{m,p} are the transconductance of the NMOS M1 and the PMOS M2, respectively.

For a given W/L of the transistors of the inverter 101, the Gm can be expressed as a function of the inverter supply voltage Vd.

The biasing circuit 102 may correspond to a suitable (e.g., conventional) complementary constant-Gm biasing circuit, where the back gates of the respective transistors of the biasing circuit 102 and the inverter 101 are additionally interconnected.

For example, the biasing circuit 102 may regulate the inverter supply voltage Vd such that the Gm of the inverter 101 can be maintained constant. Generally, the biasing circuit 102 may comprise a start-up segment, a current mirror segment, and a control segment.

For example, the start-up segment of the biasing circuit 102 may comprise a PMOS M12, which may act as the start-up or regulator for the biasing circuit 102 in order to avoid the lower values of the supply vdd of the biasing circuit 102, such as to minimize (e.g., avoid) feeding the lower values of supply voltage Vd to the inverter 101. In addition, the PMOS M12 may enter in triode region for the upper values of the supply voltage Vd to the inverter 101, thereby limiting the inverter supply voltage Vd to Vd,max.

For example, the current mirror segment may comprise any (e.g., suitable) CMOS current mirror arrangement. For example, the current mirror branches of the biasing circuit 102 may comprise complementary pairs of PMOS M8 and NMOS M11, and PMOS M10 and NMOS M13 in order to replicate the current from one branch to the other branch.

For example, the control segment of the biasing circuit 102 may comprise a first CMOS block comprising PMOS M4, NMOS M3, and NMOS M7, where the CMOS M3 and M4 pair may be a scaled version of the CMOS M1 and M2 pair of the inverter 101. Additionally, the control segment of the biasing circuit 102 may comprise a second CMOS block comprising PMOS M6, NMOS M5, and NMOS M9, where the CMOS M5 and M6 pair may be a scaled version of the CMOS M1 and M2 pair of the inverter 101.

The term scaled version should be understood as having a proportional W/L ratio of the transistors. Moreover, the first CMOS block and the second CMOS block may be connected to the respective current mirror branches of the biasing circuit 102.

In this regard, the first CMOS block or the second CMOS block may provide the resistive control for controlling the Gm of the inverter 101. In this example, the source terminals of the PMOS M6, the NMOS M5, and the NMOS M9 are connected to the respective supply via a variable or tunable resistor R.

For example, the respective back gates of the transistors of the first CMOS block, the second CMOS block, and the inverter 101 may be interconnected. For example, the back gates of the PMOS M4, the PMOS M6, and the PMOS M2 may be interconnected. Additionally, the back gates of the NMOS M3, the NMOS M5, the NMOS M7, the NMOS M9, and the NMOS M1 may be interconnected.

For example, the control circuit 103 may comprise or be an OPAMP 401. The non-inverting terminal of the OPAMP 401 may be connected to the inverter supply Vd and the inverting terminal of the OPAMP 401 may be supplied with a reference voltage, such as the threshold voltage Vd,max, such that the OPAMP 401 may compare the supply voltage Vd with the threshold voltage Vd,max.

For example, the inverting output of the OPAMP 401 may be connected to the interconnected back gates of the PMOS transistors, such as the back gates of the PMOS M2, the PMOS M4, and the PMOS M6. Additionally, the non-inverting output of the OPAMP 401 may be connected to the interconnected back gates of the NMOS transistors, such as the back gates of the NMOS M1, the NMOS M3, the NMOS M5, the NMOS M7, and the NMOS M9.

In this regard, the Gm of the CMOS M3/M4 can be expressed as:

G_{m,34}∝R

Since the CMOS M3/M4 may be a scaled version of the CMOS M1/M2 of the inverter 101, the Gm of the CMOS M1/M2 can be expressed as:

G_{m,12}∝R

Accordingly, the resistor R can be varied in order to regulate or to control the G_{m,12}, and the resistor R is constant across temperature and supply voltage variations.

In order to regulate the Gm range as well as the supply voltage range of the inverter 101, the OPAMP 401 may (e.g., continuously) sense the supply voltage Vd with respect to the threshold voltage Vd,max. If the supply voltage Vd is less than the threshold voltage Vd,max, the OPAMP 401 may (e.g., only) maintain the supply voltage Vd for the CMOS transistors by disabling the bias voltage to the respective interconnected back gates of the CMOS transistors.

For example, the OPAMP 401 may set the bias voltage V_{BP} to vdd for the interconnected back gates of the PMOS transistors, such as the back gates of the PMOS M2, the PMOS M4, and the PMOS M6, and may set the bias voltage V_{BN} to zero for the interconnected back gates of the NMOS transistors, such as the back gates of the NMOS M1, the NMOS M3, the NMOS M5, the NMOS M7, and the NMOS M9.

For example, if the supply voltage Vd is greater than the threshold voltage Vd,max, the OPAMP 401 may maintain the respective supply voltage for the CMOS transistors, whereby additionally feeding the bias voltage to the respective interconnected back gates of the CMOS transistors.

For example, the OPAMP 401 may set the bias voltage V_{BP} to zero for the interconnected back gates of the PMOS transistors, such as the back gates of the PMOS M2, the PMOS M4, and the PMOS M6, and may set the bias voltage V_{BN} to vdd for the interconnected back gates of the NMOS transistors, such as the back gates of the NMOS M1, the NMOS M3, the NMOS M5, the NMOS M7, and the NMOS M9, such as to maintain the PMOS M12 in the saturation region.

The following table provides an example illustration of the voltage transitions for the bias voltage applied at the interconnected back gates of the CMOS transistors.

| Vd | V_{BP} | V_{BN} |
|---|---|---|
| <Vd,max | vdd | 0 |
| Slightly more | Transition | Transition |
| than Vd,max | from vdd to 0 | from 0 to vdd |
| >Vd,max | 0 | vdd |

Accordingly, both the control circuit 103 and biasing circuit 102 may together increase the tuning range of the G_{m,12} of the inverter 101, whereby (e.g., simultaneously) providing the (e.g., automatic) tuning of the G_{m,12} of the inverter 101.

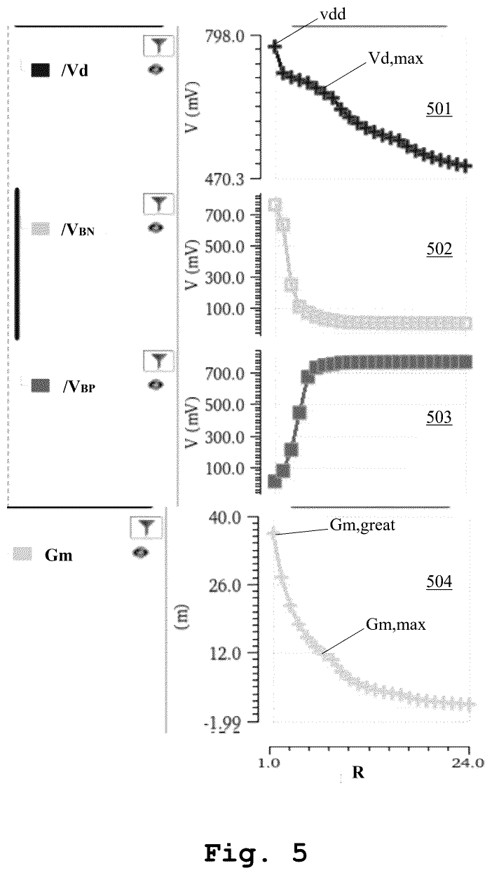

In FIG. 5, an exemplary tuning effect of the resistor R on the parameters of the CMOS inverter 101 is illustrated. The plot 501 illustrates the variation of the inverter supply voltage Vd with the tuning of the resistor R, the plot 502 illustrates the variation of the NMOS back gate bias voltage V_{BN} with the tuning of the resistor R, the plot 503 illustrates the variation of the PMOS back gate bias voltage V_{BP} with the tuning of the resistor R, and the plot 504 illustrates the variation of the Gm of the inverter 101 with the tuning of the resistor R.

In the plots 501-504, the voltages are shown in millivolt (mV), the Gm is shown in millisiemens (mS), and the resistance is shown in ohm.

In one example, it can be seen that above about 10 mS, Vd reaches Vd,max. Therefore, in this example and in relation to FIG. 3B, the Gm,max of the inverter 101 is about 10 mS. However, due to the application of the bias voltage to the interconnected back gates of the transistors, the maximum possible supply voltage range of the inverter is extended to vdd, e.g., the supply of the biasing circuit, and the Gm range of the inverter 101 is extended to about 35 mS. Accordingly, in this example and in relation to FIG. 3B, the vbg,max is the vdd and the Gm, great is about 35 mS.

Furthermore, the transition for the back gate bias voltage V_{BN} from vdd to 0 at the interconnected NMOS transistors is shown in the plot 502. Moreover, the transition for the back gate bias voltage V_{Bp} from 0 to vdd at the interconnected PMOS transistors is shown in the plot 503.

As such, the previous Gm tuning range of 2 mS to 10 mS of the inverter 101 is successfully extended to provide a wider Gm tuning range of 2 mS to greater than 30 mS.

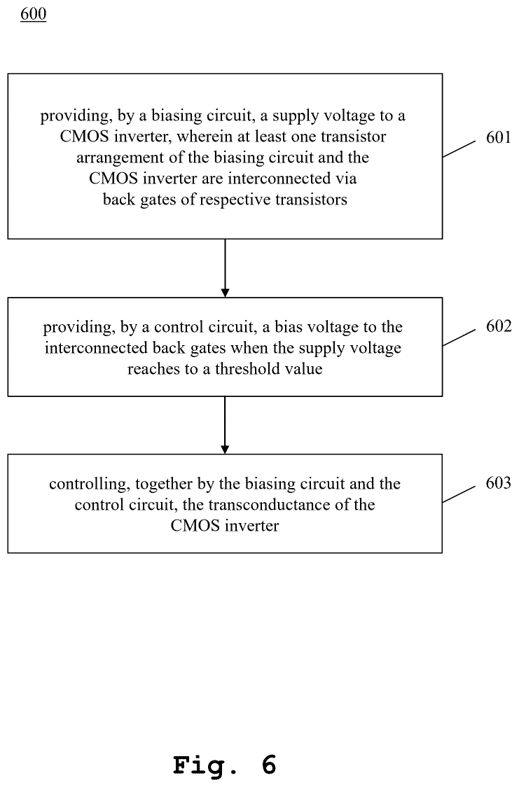

In FIG. 6, an exemplary embodiment of the method 600 according to the second embodiment of the disclosure is illustrated. In a first step 601, a supply voltage is provided to a CMOS inverter by a biasing circuit, where at least one transistor arrangement of the biasing circuit and the CMOS inverter are interconnected via back gates of respective transistors.

In a second step 602, a bias voltage is provided to the interconnected back gates by a control circuit when the supply voltage reaches a threshold value. In a third step 603, the transconductance of the CMOS inverter is controlled together by the biasing circuit and the control circuit.

It is noted that, in the description as well as in the claims, the word “comprising” does not exclude other elements or steps and the indefinite article “a” or “an” does not exclude a plurality. A single element or other unit may fulfill the functions of several entities or items recited in the claims.

It should be understood that the term “and/or” used in the specification and the appended claims of this application refers to any combination and all possible combinations of one or more associated listed items, and includes these combinations.

It should also be understood that the word “connected” implies that the elements may be directly connected together or may be coupled through one or more intervening elements. Moreover, the disclosure with regard to any of the embodiments is also relevant with regard to the other embodiments of the disclosure.

Although the disclosure has been illustrated and described with respect to one or more implementations, equivalent alterations and modifications will occur to others skilled in the art upon the reading and understanding of this specification and the annexed drawings. In addition, while a (e.g., particular) feature of the disclosure may have been disclosed with respect to (e.g., only) one of several implementations, such feature may be combined with one or more other features of the other implementations as may be (e.g., desired) for any given application. The mere fact that (e.g., certain) measures or features are recited in mutually different dependent claims does not indicate that a combination of these measures or features cannot be used. Any reference signs in the claims should not be construed as limiting the scope.

What is claimed is:

1. A system for increasing transconductance of a Complementary Metal-Oxide Semiconductor (CMOS) inverter, the system comprises:
a biasing circuit configured to provide a supply voltage to the CMOS inverter, wherein the biasing circuit comprises at least one transistor arrangement, wherein the transistor arrangement and the CMOS inverter are interconnected via back gates of respective transistors, and
a control circuit configured to provide a bias voltage to the interconnected back gates when the supply voltage reaches a threshold value, whereby both the biasing circuit and the control circuit together control the transconductance of the CMOS inverter.

2. The system according to claim 1, wherein the control circuit is further configured to maintain the supply voltage to the CMOS inverter when the supply voltage is higher than the threshold value.

3. The system according to claim 1, wherein the transistor arrangement comprises at least one replicated CMOS inverter corresponding to a scaled version of the CMOS inverter and at least one resistor, wherein the at least one resistor is a tunable resistor, operably connected to the replicated CMOS inverter.

4. The system according to claim 1, wherein the biasing circuit is configured to provide the supply voltage ranging from a predefined minimum value to the threshold value.

5. The system according to claim 4, wherein the predefined minimum value is based on a minimum linearity criteria of the transconductance of the CMOS inverter.

6. The system according to claim 4, wherein the transistor arrangement of the biasing circuit is configured to control the transconductance of the CMOS inverter for the supply voltage ranging from the predefined minimum value to the threshold value.

7. The system according to claim 1, wherein the control circuit is configured to provide the bias voltage to the interconnected back gates ranging from zero to a supply voltage of the biasing circuit.

8. The system according to claim 7, wherein the transistor arrangement of the biasing circuit is configured to control the transconductance of the CMOS inverter for the bias voltage to the interconnected back gates ranging from zero to the supply voltage of the biasing circuit.

9. The system according to claim 1, wherein the control circuit comprises at least one comparator wherein the at least one comparator is an operational amplifier comparator, configured to sense the supply voltage from the biasing circuit and further to compare the supply voltage with the threshold value.

10. The system according to claim 9, wherein the comparator is further configured to feed the supply voltage to the transistor arrangement and the CMOS inverter when the supply voltage is lower than the threshold value.

11. The system according to claim 10, wherein the comparator is further configured to additionally feed the bias voltage to the interconnected back gates of the respective transistors of the transistor arrangement and the CMOS inverter when the supply voltage reaches the threshold value.

12. The system according to claim 4, wherein the transconductance is inversely proportional to a resistor of the transistor arrangement.

13. The system according to claim 4, wherein the threshold value is based on an operation criteria of the transistor arrangement.

14. The system according to claim 3, wherein the transistor arrangement is configured to control the transconductance of the CMOS inverter with the replicated CMOS inverter and a resistor.

15. The system according to claim 1, wherein the respective transistors of the transistor arrangement and the CMOS inverter are Fully-Depleted Silicon-on-Insulator (FDSOI) transistors.

16. A method for increasing transconductance of a complementary metal oxide semiconductor (CMOS) inverter, the method comprises:
providing, by a biasing circuit, a supply voltage to the CMOS inverter, wherein at least one transistor arrangement of the biasing circuit and the CMOS inverter are interconnected via back gates of respective transistors,
providing, by a control circuit, a bias voltage to the interconnected back gates when the supply voltage reaches a threshold value, and
controlling, together by the biasing circuit and the control circuit, the transconductance of the CMOS inverter.

17. The method according to claim 16, wherein the method further comprises maintaining, by the control circuit, the supply voltage to the CMOS inverter when the supply voltage is higher than the threshold value.

18. The method according to claim 16, wherein the method further comprises:
providing, by the biasing circuit, the supply voltage ranging from a predefined minimum value to the threshold value, and
providing, by the control circuit, the bias voltage to the interconnected back gates ranging from zero to a supply voltage of the biasing circuit.

19. The method according to claim 18, wherein the method further comprises controlling, by the transistor arrangement, the transconductance of the CMOS inverter for the supply voltage ranging from the predefined minimum value to the threshold value.

20. The method according to claim 18. wherein the method further comprises
controlling, by the transistor arrangement, the transconductance of the CMOS inverter for the bias voltage to the interconnected back gates ranging from zero to the supply voltage of the biasing circuit.
